(19) United States
(12) Patent Application Publication
(10) Pub. No.: US 2015/0122331 A1
(43) Pub. Date: May 7, 2015

(54) ENCAPSULATING SHEET FOR SOLAR CELL, SOLAR CELL, AND METHOD FOR MANUFACTURING SOLAR CELL

(71) Applicant: Mitsui Chemicals Tohcello, Inc., Chiyoda-ku, Tokyo (JP)

(72) Inventors: Hiroyuki Kuroda, Mobara-shi (JP); Takatoshi Yaoita, Chiba-shi (JP); Shigeyuki Shishido, Kamakura-shi (JP); Yukihiro Iwasaki, Mobara-shi (JP); Takafumi Mori, Yokohama-shi (JP)

(73) Assignee: Mitsui Chemicals Tohcello, Inc., Chiyoda-ku, Tokyo (JP)

(21) Appl. No.: 14/378,494

(22) PCT Filed: Feb. 7, 2013
(86) PCT No.: PCT/JP2013/000668

§ 371 Date: Aug. 13, 2014

(30) Foreign Application Priority Data
Feb. 15, 2012 (JP) 2012-030880

(51) Int. Cl. H01L 31/048

(52) U.S. Cl. CPC H01L 31/048; H01L 31/0481
USPC 136/259; 136/252; 438/64

(57) ABSTRACT

An encapsulating sheet for solar cell for encapsulating a solar cell, in which, in a case in which a square sheet obtained by cutting the sheet so that a planar shape becomes a square shape is heated at the atmospheric pressure and 150° C. for 15 minutes and is thus thermally shrunk, when a length of one side of the square sheet before being thermally shrunk is represented by L, a direction in parallel with a first side is considered as a first direction, and a direction perpendicular to the first side is considered as a second direction, and in the thermally-shrunk square sheet, a shortest length in the first direction is represented by M1, and a shortest length in the second direction is represented by M2, 0≦|(M1−M2)/L|≦0.4 is satisfied.

### TECHNICAL FIELD

The present invention relates to an encapsulating sheet for solar cell, a solar cell, and a method for manufacturing a solar cell.

### BACKGROUND ART

Patent Document 1 discloses an encapsulating sheet for solar cell obtained by forming an ethylene-vinyl acetate copolymer (EVA) resin film.

The above-described encapsulating sheet for solar cell is generally manufactured by extruding a heated and kneaded material in a sheet shape from a die installed in an extruder such as a T die.

### RELATED DOCUMENT

### Patent Document

[Patent Document 1] Japanese Patent No. 3473605

### DISCLOSURE OF THE INVENTION

The present inventors found that, when an encapsulating sheet for solar cell of the related art is heated under predetermined conditions (in the atmospheric pressure, at a temperature of 150° C., and for 15 minutes), the encapsulating sheet for solar cell is anisotropically shrunk. The above-described anisotropic shrinkage is presumed to be caused by a stress remaining during the molding of the sheet.

Meanwhile, among encapsulating sheets for solar cell of the related art, there are encapsulating sheets for solar cell that are heated after being extruded from an extruder to alleviate the stress during the molding of the sheet. However, the inventors found that, when an encapsulating sheet for solar cell that has been subjected to the above-described stress-alleviating treatment is heated under the above-described conditions, the encapsulating sheet for solar cell becomes anisotropically shrunk in the same manner. The above-described finding is presumed to result from the fact that, in the related art, there was no understanding that it is necessary to alleviate the stress (to heat the sheet) until the anisotropic shrinkage caused by heating under the above-described conditions can be avoided.

The above-described predetermined conditions are conditions that simulate a heating and pressurization treatment when a solar cell is encapsulated using the encapsulating sheets for solar cell, and the fact that the encapsulating sheet for solar cell is anisotropically shrunk due to heating under the above-described predetermined conditions indicates that the encapsulating sheet for solar cell is anisotropically shrinkable during an encapsulating treatment.

Generally, the encapsulating treatment is carried out by cutting out an encapsulating sheet for solar cell having a predetermined shape from a raw material roll (a roll of the encapsulating sheet for solar cell), then, forming a laminate obtained by sandwiching a solar cell using the encapsulating sheets for solar cell, and then heating and pressurizing the laminate. In a case in which the encapsulating sheet for solar cell is anisotropically shrunk due to the heating and pressurization at this time, needless to say, it is necessary to design the shape of the encapsulating sheet for solar cell being cut out (the cut shape) in consideration of the above-described shrinkage.

It goes without saying that a work for designing the cut shape in consideration of the above-described anisotropic shrinkage is troublesome and takes an effort. In addition, while depending on the desired shape after shrinkage as well, the cut shape before shrinkage is likely to become a shape having different vertical and horizontal lengths such as a rectangular shape. In such a case, it becomes difficult to cut the encapsulating sheet for solar cell from the raw material roll with no waste, and loss is likely to occur.

As a result, an object of the invention is to reduce disadvantages such as the effort for designing the above-described cut shape of the encapsulating sheet for solar cell.

According to the invention, there is provided an encapsulating sheet for solar cell for encapsulating a solar cell, in which, in a case in which a square sheet obtained by cutting the sheet so that a planar shape becomes a square shape is heated at the atmospheric pressure and 150° C. for 15 minutes and is thus thermally shrunk, when a length of one side of the square sheet before being thermally shrunk is represented by L, a direction in parallel with a first side is considered as a first direction, and a direction perpendicular to the first side is considered as a second direction, and in the thermally-shrunk square sheet, a shortest length in the first direction is represented by M1, and a shortest length in the second direction is represented by M2, 0≦|(M1−M2)/L|≦0.4 is satisfied.

In addition, according to the invention, there is provided a solar cell obtained by encapsulating a solar cell using the encapsulating sheets for solar cell.

In addition, according to the invention, there is provided a method for manufacturing a solar cell including an encapsulating step in which a laminate obtained by sandwiching a solar cell using the encapsulating sheets for solar cell is formed, and the laminate is integrated by heating and pressurization.

According to the invention, it is possible to reduce disadvantages such as the effort for designing the cut shape of the encapsulating sheet for solar cell.

### BRIEF DESCRIPTION OF THE DRAWINGS

The above-described object, other objects, characteristics, and advantages will be further clarified using preferable embodiments described below and the following drawings accompanied by the embodiments.

FIG. 1 is a planar view schematically illustrating a state in which a square sheet obtained by cutting an encapsulating sheet for solar cell of the present embodiment so that the planar shape becomes a square shape is thermally shrunk under first conditions (in the atmospheric pressure, at a temperature of 150° C., and for 15 minutes).

FIG. 2 is a planar photograph illustrating a state in which encapsulating sheets for solar cell of an example and a comparative example are cut so that the planar shape becomes a square shape, and then is thermally shrunk under the first conditions (in the atmospheric pressure, at a temperature of 150° C., and for 15 minutes).

FIG. 3 is a conceptual view for describing a step of an example of a method for molding the sheet of the embodiment.

FIG. 4 is a view illustrating the frequency dependencies of the storage modulus and loss modulus of each of a polyolefin-based resin (PO) and an ethylene-vinyl acetate copolymer (EVA) resin.

### DESCRIPTION OF EMBODIMENTS

Hereinafter, embodiments of the invention will be described based on the drawings. Meanwhile, in all the drawings, the same components will be given the same reference numerals and will not be repeated.

<Encapsulating Sheet for Solar Cell>

In the embodiment, to reduce disadvantages that may be caused by the anisotropic shrinkage when the encapsulating sheet for solar cell is heated under first conditions (in the atmospheric pressure, at a temperature of 150° C., and for 15 minutes) such as an effort for designing the cut shape of an encapsulating sheet for solar cell, there is provided an encapsulating sheet for solar cell that is substantially isotropically shrunk when heated under the same conditions.

That is, in a case in which a square sheet obtained by cutting the encapsulating sheet for solar cell of the embodiment so that the planar shape becomes a square shape is heated under the first conditions (in the atmospheric pressure, at a temperature of 150° C., and for 15 minutes) and is thus thermally shrunk, when the length of one side of the square sheet before being thermally shrunk is represented by L (100 mm≦L≦150 mm), the direction in parallel with a first side (an arbitrary side of four sides) is considered as a first direction, and the direction perpendicular to the first side is considered as a second direction, and, in the thermally-shrunk square sheet, the shortest length in the first direction is represented by M1, and the shortest length in the second direction is represented by M2, the encapsulating sheet for solar cell of the embodiment satisfies 0≦|(M1−M2)/L|≦0.4.

Meanwhile, the encapsulating sheet for solar cell of the embodiment preferably satisfies 0≦|(M1−M2)/L|≦0.2, and more preferably satisfies 0≦|(M1−M2)/L|≦0.1. In a case in which the above-described preferable condition is satisfied, it is possible to more effectively reduce disadvantages such as the effort for designing the cut shape of the encapsulating sheet for solar cell that may be caused by the anisotropic shrinkage when the encapsulating sheet for solar cell is heated under first conditions (in the atmospheric pressure, at a temperature of 150° C., and for 15 minutes).

Meanwhile, the “heat treatment under the first conditions (in the atmospheric pressure, at a temperature of 150° C., and for 15 minutes)” is carried out using a hot plate.

In addition, the above-described M1 and M2 are values measured after the heat-treated square sheet is left to stand until the square sheet is naturally cooled to room temperature. When the square sheet is directly placed on a table, there is a case in which the square sheet is adhered to the table, which hinders shrinkage. Therefore, during the measurement, powder is dispersed on a surface on which the sheet after the heat treatment is placed to prevent natural shrinkage from being hindered.

When the encapsulating sheet for solar cell of the embodiment is heated as described above and M1 and M2 are measured as described above, the above-described condition becomes satisfied.

Meanwhile, the encapsulating sheet for solar cell of the embodiment preferably satisfies 0.3≦M1/L≦1 and 0.3≦M2/L≦1. Furthermore, the encapsulating sheet for solar cell of the embodiment preferably satisfies 0.5≦M1/L≦1 and 0.5≦M2/L≦1, and more preferably satisfies 0.7≦M1/L≦1 and 0.7≦M2/L≦1. In such a case, the effort for designing the cut shape of the encapsulating sheet for solar cell is further reduced. In addition, there is no waste of the encapsulating sheet for solar cell, and cost advantage is also obtained.

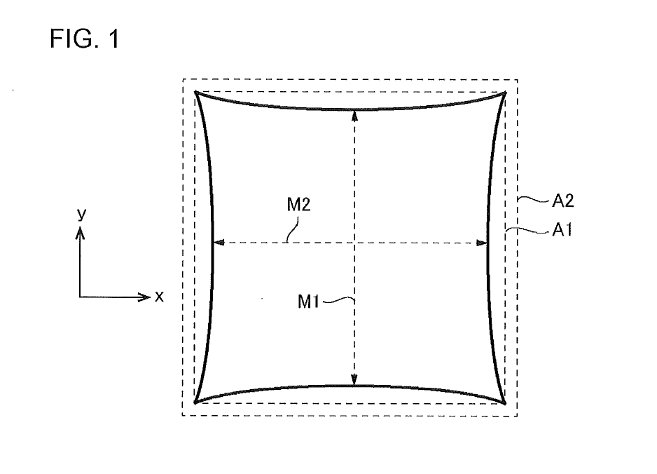

FIG. 1 is a view schematically illustrating a square sheet made of the encapsulating sheet for solar cell of the embodiment and a state in which the square sheet has been heated under the first conditions. The state of the square sheet before heating is indicated using a dotted line A1 or A2, and the state of the square sheet after heating is indicated using a solid line. Both the x direction and the y direction in the drawing are directions that are in parallel with any one of the sides of the square sheet before heating.

As illustrated in the drawing, in a case in which the square sheet made of the encapsulating sheet for solar cell of the embodiment is heated under the first conditions, shrinkage in the x direction and shrinkage in the y direction exhibit the same behavior.

Regarding the tendency of the shrinkage, the square sheet tends to shrink more in the vicinities of the centers of the four sides than in the vicinities of four corner points. Therefore, both M1 and M2 tend to be located in the vicinities of the centers of the four sides as illustrated in the drawing.

Meanwhile, there are both cases in which the square sheet is shrunk in the vicinities of the four corner points and the square sheet is not shrunk in the vicinities of the four corner points. That is, the state of the square sheet before heating is either A1 or A2. In addition, there is a variation in the degree of shrinkage to a certain extent in a case in which the square sheet is shrunk in the vicinities of the four corner points. However, roughly, the tendencies of shrinkage (the degree of shrinkage and the like) in the vicinities of the four corner points exhibit the same tendency.

According to the above-described encapsulating sheet for solar cell of the embodiment, it is possible to reduce disadvantages such as the effort for designing the cut shape of the encapsulating sheet for solar cell that may be caused by the anisotropic shrinkage when the encapsulating sheet for solar cell is heated under the first conditions (in the atmospheric pressure, at a temperature of 150° C., and for 15 minutes).

<Manufacturing Method>

Next, an example of a method for manufacturing the encapsulating sheet for solar cell of the embodiment will be described. For example, when an encapsulating sheet for solar cell is manufactured using the following method for manufacturing a sheet, the encapsulating sheet for solar cell of the embodiment having the above-described characteristics is obtained. Hereinafter, a method for manufacturing a sheet will be first described, and then an example in which an encapsulating sheet for solar cell is manufactured using the above-described method for manufacturing a sheet will be described.

“Method for Manufacturing a Sheet”

The inventors presumed that the disadvantage of a molded sheet being changed in the dimensions from the subsequent heating is due to the fact that the sheet was cooled and solidified while an orientation or stress generated in the sheet when the sheet was molded by extruding a molten resin remained in the sheet.

Therefore, the inventors studied a technique that sufficiently increased the distance (air gap) from a die outlet to a cooling roll or sufficiently decreased the moving speed of a sheet from the die outlet to the cooling roll, thereby sufficiently alleviating the orientation or stress before the sheet extruded from a die was cooled and solidified. According to the above-described technique that sufficiently alleviates the orientation or stress and then cools and solidifies the sheet, there is a possibility that a disadvantage of the orientation or stress remaining in the sheet is eliminated and a disadvantage of the molded sheet being anisotropically changed in the dimensions due to the subsequent heating can be eliminated.

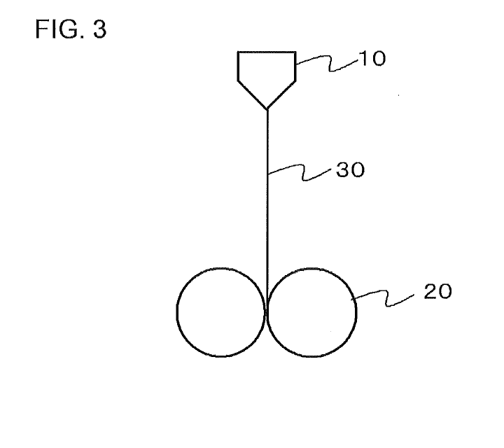

The method for manufacturing a sheet of the embodiment includes a molding step in which a thermoplastic resin is melted and extruded from a die of an extrusion molder in a sheet shape, then, is made to pass through a pair of cooling rolls, and is cooled and solidified. FIG. 3 illustrates a conceptual view of the molding step.

As illustrated in FIG. 3, a resin sheet 30 extruded from a die 10 of an extrusion molder in a sheet shape is subsequently made to pass through a pair of cooling rolls 20, thereby being cooled and solidified. Meanwhile, an embossing process may be carried out on the sheet surface by providing recess portions and/or protrusion portions to the surface of the cooling rolls 20. Steps before and after the molding step can be designed according to the related art, and thus will not be described here.

The method for manufacturing a sheet of the embodiment includes a technique capable of appropriately setting the conditions of the molding step so as to reduce the disadvantage of a molded sheet being changed in the dimensions due to the subsequent heating without the occurrence of a disadvantage that the line speed becomes too slow or the facility installation space becomes too large.

Specifically, in the method for manufacturing a sheet of the embodiment, the conditions are set so that the average strain rate d∈/dt [sec⁻¹] obtained using the following formula and the frequency ω_{d} [sec⁻¹] that is the inverse of the longest relaxation time (hereinafter, referred to as relaxation time) of the thermoplastic resin obtained using the storage modulus (G′) and loss modulus (G″) of the thermoplastic resin satisfy a relationship of d∈/dt<ω_{d} at an average resin temperature that is the temperature of the sheet-shaped thermoplastic resin (the resin sheet 30) in midway between the die 10 and the cooling rolls 20.

d∈/dt=(V1/Z)ln(V1/V0) (Formula)

V0 represents the rate [mm·sec⁻¹] of the thermoplastic resin being extruded from the extrusion molder, V1 represents the drawing rate [mm·sec⁻¹] of the sheet-shaped thermoplastic resin (the resin sheet 30), and Z represents the air gap [mm] between an outlet of the die 10 through which the thermoplastic resin is extruded and the cooling rolls 20. Meanwhile, V0 is obtained by dividing the volume rate of the thermoplastic resin being extruded by the lip cross-sectional area, and V1 is obtained as the rotation circumferential speed of the roll 20.

When the conditions are set within a range in which d∈/dt<ω_{d} is satisfied so as to prevent V1 and V0 from becoming too small and Z from becoming too great, it is possible to reduce the disadvantage of the line speed becoming too slow and the facility installation space becoming too great.

Meanwhile, the conditions may be controlled so that the relationship of d∈/dt<ω_{d} is satisfied in a temperature that is equal to or lower than the temperature of the resin immediately after being extruded from the die 10 and equal to or higher than the temperature of the resin immediately before being sandwiched by the cooling rolls 20.

The average resin temperature in the middle between the die 10 and the cooling rolls 20, the temperature of the resin immediately after being extruded from the die 10, and the temperature of the resin immediately before being sandwiched by the cooling rolls 20 can be measured using, for example, an infrared thermometer.

Here, the frequency ω_{d} [sec⁻¹] will be described. As described above, the frequency ω_{d} is the inverse of the relaxation time of the thermoplastic resin obtained using the storage modulus (G′) and loss modulus (G″) of the thermoplastic resin.

The relaxation time can be estimated from the behaviors of the storage modulus (G′) and loss modulus (G″) on the low-frequency side of the thermoplastic resin obtained through melt viscoelasticity measurement. Specifically, on the low-frequency side, G′ indicates the behavior of a slope 2, and G″ indicates the behavior of a slope 1, and therefore G′ and G″ are fitted to data, and the frequency at which the approximate lines intersect with each other is obtained. When the frequency is inversed, the relaxation time is obtained.

The melt viscoelasticity is measured using a viscoelasticity measuring instrument (for example, an (ARES-type) viscoelasticity tester manufactured by TA Instruments). Specifically, a specimen formed by obtaining 2 mm-thick sheet through pressing at 120° C., and then molding the sheet into a disc having a diameter of 25 mm and a thickness of 2 mm is used, and the measurement is carried out under the following conditions. Meanwhile, RSI Orchestrator VER. 6.6.3 (manufactured by TA Instruments Japan Inc.) is used as data-processing software.

Geometry: parallel plate

Measurement temperature: 120° C. (a temperature that is equal to or higher than the melting point)

Frequency: 0.01 rad/sec to 100 rad/sec

Distortion ratio: 1.0%

According to the above-described method for manufacturing a sheet, when the melt viscoelasticity of the thermoplastic resin used to mold a sheet is measured so as to compute the frequency ω_{d} [sec⁻¹], and then V0, V1, and Z are set so that d∈/dt<ω_{d} is satisfied, it is possible to form a sheet in which the orientation or stress is sufficiently alleviated. As a result, it is possible to reduce the disadvantage of the formed sheet being changed in the dimensions due to the subsequent heating. Therefore, it is possible to avoid a disadvantage that a sheet cut into a predetermined shape is shrunk and changed in the shape due to the subsequent heating, and becomes incapable of performing predetermined functions.

In addition, when the conditions are set so as to prevent V1 and V0 from becoming too small and to prevent Z from becoming too great within a range in which d∈/dt<ω_{d} is satisfied, it is possible to suppress a disadvantage that the line speed becomes unnecessarily slow or the facility installation space becomes unnecessarily great.

“Method for Manufacturing an Encapsulating Sheet for Solar Cell”

Next, a method for manufacturing an encapsulating sheet for solar cell using the above-described method for manufacturing a sheet will be described. An encapsulating sheet for solar cell of the embodiment contains a thermoplastic resin and at least one additive. First, materials will be described.

(Thermoplastic Resin)

There is no particular limitation to the kind of the thermoplastic resin, and, for example, a polyolefin-based resin or an ethylene-vinyl acetate copolymer resin can be used. However, among the above-described resins, the polyolefin-based resin is preferably used. Hereinafter, the reason for the preference will be described.

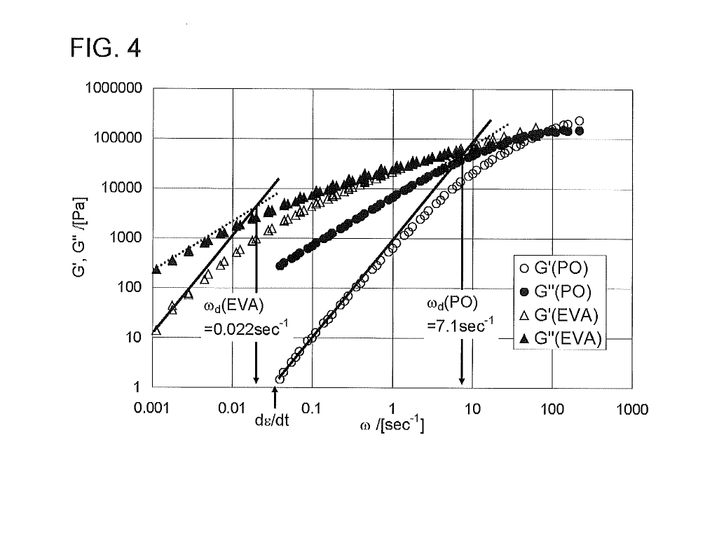

FIG. 4 illustrates the frequency dependencies (logarithm-logarithm plot) of the viscoelasticity of each of the polyolefin-based resin (PO) and the ethylene-vinyl acetate copolymer (EVA) resin at 70° C. The vertical axis indicates the storage modulus (G′) and loss modulus (G″), and the horizontal axis indicates the frequency. The relaxation time is obtained from the measurement data in a region, called a fluidic region, in which the complex viscosity is not dependent on the frequency and is constant. Specifically, the intersection point of extrapolation lines of data is obtained using the data in which G′ exhibits the slope 2 and G″ exhibits the slope 1. The frequency at which the intersection point is present serves as the frequency ω_{d} [sec⁻¹] that is an inverse of the relaxation time.

FIG. 4 illustrates that ω_{d} [sec⁻¹] is larger for PO than for EVA. Therefore, the range in which d∈/dt satisfying d∈/dt<ω_{d} can be obtained is greater for PO than for EVA. As a result, the width of the design of V1, V0, and Z is wider for PO than for EVA. Even in the case of PO, the orientation or stress is not sufficiently alleviated using the setting of V1, V0, and Z, and the formula of the invention is not satisfied.

The encapsulating sheet for solar cell of the invention can be obtained by selecting the conditions for processing a molten resin into a sheet, but the sheet of the invention can also be obtained using other methods. Since the orientation or stress is not sufficiently alleviated in a sheet obtained under process conditions in which the formula d∈/dt<ω_{d} is not satisfied unlike what has been described above, the formula 0≦|(M1−M2)/L|≦0.4 is not satisfied in this case. However, it is possible to obtain the encapsulating sheet for solar cell of the invention by carrying out an annealing treatment in a sheet state so as to alleviate the orientation. Specifically, when heating is carried out at a temperature that is lower than the melting point and near the softening point of a resin used to form the sheet, it is possible to alleviate the orientation while maintaining the sheet shape. The heating time can be appropriately set, and is preferably several hours to approximately one day.

(Polyolefin-Based Resin)

In the embodiment, there is no particular limitation to the polyolefin-based resin, and examples thereof include low-density ethylene-based resins, intermediate-density ethylene-based resins, ultralow-density ethylene-based resins, propylene (co)polymers, 1-butene (co)polymers, 4-methylpentene-1 (co)polymers, ethylene/α-olefin copolymers, ethylene/cyclic olefin copolymers, ethylene/α-olefin/cyclic olefin copolymers, ethylene/α-olefin/non-conjugated polyene copolymers, ethylene/α-olefin/conjugated polyene copolymers, ethylene/aromatic vinyl copolymers, ethylene/α-olefin/aromatic vinyl copolymers, and the like. The above-described polyolefin-based resins may be solely used or may be used in a mixture of two or more.

Among the above-described polyolefin-based resins, the ethylene/α-olefin copolymers composed of ethylene and an α-olefin having 3 to 20 carbon atoms are particularly preferred since the balance among a variety of characteristics required for the encapsulating sheet for solar cell such as transparency, adhesiveness, flexibility, heat resistance, appearance, crosslinking characteristics, electrical characteristics, and extrusion molding properties is excellent.

The melt flow rate (MFR) of the polyolefin-based resin in the embodiment, which is based on ASTM D1238 and measured under conditions of a temperature of 190° C. and a load of 2.16 kg, is preferably in a range of 0.1 g/10 minutes to 50 g/10 minutes, more preferably in a range of 3 g/10 minutes to 40 g/10 minutes, and further more preferably in a range of 10 g/10 minutes to 27 g/10 minutes. MFR of the polyolefin-based resin can be adjusted by adjusting the polymerization temperature and polymerization pressure in a polymerization reaction, the molar ratio between the monomer concentration and the hydrogen concentration in ethylene in a polymerization system, and the like.

When MFR is equal to or more than 3 g/10 minutes, the fluidity of the encapsulating sheet for solar cell improves, and it is possible to improve the productivity during sheet extrusion molding. In addition, the scorch property of the encapsulating sheet for solar cell degrades, and therefore it is possible to suppress gelatinization. Therefore, the torque of an extrusion molder decreases, and thus sheet molding can be facilitated. In addition, since it is possible to suppress the generation of a gel-form substance in the extruder after a sheet is obtained, it is possible to suppress the sheet surface becoming uneven and to suppress the degradation of the appearance. Ina case in which MFR is less than 10 g/10 minutes, particularly, less than 3 g/10 minutes, the fluidity is low, and thus it is also possible to mold a sheet through calendar molding.

In addition, when the sheet surface becomes uneven, the tight adhesiveness among a glass plate, a cell, an electrode, and a backsheet deteriorates during the lamination process of a solar cell module, and the adhesion becomes insufficient. However, when MFR is set to equal to or less than 50 g/10 minutes, the molecular weight becomes great, and therefore it is possible to suppress the attachment to a roll surface of a chilled roll or the like. Therefore peeling is not required, and a sheet having a uniform thickness can be molded. Furthermore, since the resin composition becomes “firm”, it is possible to easily mold a sheet having a thickness of equal to or more than 0.3 mm. In addition, since the crosslinking characteristic (particularly, the crosslinking rate) is improved during the lamination molding of the solar cell module, the polyolefin-based resin is sufficiently crosslinked so that the degradation of the heat resistance can be suppressed. When MFR is equal to or less than 27 g/10 minutes, furthermore, it is possible to suppress neck in during the sheet molding, to mold a sheet having a wide width, to further improve the crosslinking characteristic and the heat resistance, and to obtain the most favorable encapsulating sheet for solar cell.

The density of the polyolefin-based resin in the embodiment, which is measured on the basis of ASTM D1505, is preferably in a range of 0.865 g/cm³ to 0.884 g/cm³. The density of the polyolefin-based resin can be adjusted using the content ratio of an ethylene unit. That is, when the content ratio of the ethylene unit is increased, the crystallinity increases, and the polyolefin-based resin having a high density can be obtained. On the other hand, when the content ratio of the ethylene unit is decreased, the crystallinity decreases, and the polyolefin-based resin having a low density can be obtained.

When the density of the polyolefin-based resin is equal to or less than 0.884 g/cm³, the crystallinity becomes low, and it is possible to increase the transparency. Furthermore, extrusion-molding at a low temperature becomes easy, and, for example, it is possible to carry out extrusion-molding at equal to or lower than 130° C. Therefore, even when an organic peroxide is kneaded into the polyolefin-based resin, it is possible to prevent the progress of a crosslinking reaction in an extruder, to suppress the generation of a gel-form foreign substance in the sheet, and to suppress the deterioration of the appearance of the sheet. In addition, since the flexibility is high, it is possible to prevent the occurrence of cracking in a cell which is a solar cell element or the chipping of the thin film electrode during the lamination molding of the solar cell module.

On the other hand, when the density of the polyolefin-based resin is equal to or more than 0.865 g/cm³, it is possible to increase the crystallization rate of the polyolefin-based resin, and therefore a sheet extruded from an extruder does not easily become sticky, the sheet is easily peeled from a first cooling roll, and it is possible to easily obtain an encapsulating sheet for solar cell. In addition, since the sheet does not easily become sticky, it is possible to suppress the occurrence of blocking and improve the feeding property of the sheet. In addition, since the sheet is sufficiently crosslinked, it is possible to suppress the degradation of the heat resistance.

(Ethylene/α-Olefin Copolymer)

The ethylene/α-olefin copolymer composed of ethylene and an α-olefin having 3 to 20 carbon atoms in the embodiment is obtained by, for example, copolymerizing ethylene and an α-olefin having 3 to 20 carbon atoms. As the α-olefin, generally, it is possible to solely use an α-olefin having 3 to 20 carbon atoms, or to use a combination of two or more α-olefins having 3 to 20 carbon atoms. Among the above-described α-olefins, an α-olefin having 10 or less carbon atoms is preferred, and an α-olefin having 3 to 8 carbon atoms is particularly preferred.

Specific examples of the above-described α-olefin include propylene, 1-butene, 1-pentene, 1-hexene, 3-methyl-1-butene, 3,3-dimethyl-1-butene, 4-methyl-1-pentene, 1-octene, 1-decene, and 1-dodecene. Among the above-described α-olefins, propylene, 1-butene, 1-pentene, 1-hexene, 4-methyl-1-pentene, and 1-octene are preferred in terms of easy procurement. Meanwhile, the ethylene/α-olefin copolymer may be a random copolymer or a block copolymer, but is preferably a random copolymer from the viewpoint of flexibility.

The ethylene/α-olefin copolymer used in the invention preferably satisfies the following requirements a1) to a4):

a1) a content ratio of a structural unit derived from ethylene is in a range of 80 mol % to 90 mol %, and a content ratio of a structural unit derived from an α-olefin having 3 to 20 carbon atoms is in a range of 10 mol % to 20 mol %;

a2) MFR, which is based on ASTM D1238 and measured under conditions of a temperature of 190° C. and a load of 2.16 kg, is in a range of 0.1 g/10 minutes to 50 g/10 minutes;

a3) a density, which is measured on the basis of ASTM D1505, is in a range of 0.865 g/cm³ to 0.884 g/cm³; and

a4) a shore A hardness, which is measured on the basis of ASTM D2240, is in a range of 60 to 85.

The ratio of a structural unit derived from the α-olefin contained in the ethylene/α-olefin copolymer of the embodiment having 3 to 20 carbon atoms (hereinafter, also referred to as “α-olefin unit”), is preferably in a range of 10 mol % to 20 mol %.

When the ratio of the α-olefin unit is equal to or more than 10 mol %, a sheet having a high transparency can be obtained. In addition, it is possible to easily carry out extrusion-molding at a low temperature, for example, extrusion-molding at equal to or lower than 130° C. is possible.

Therefore, even in a case in which an organic peroxide is kneaded into the ethylene/α-olefin copolymer, it is possible to suppress the progress of a crosslinking reaction in an extruder, and to prevent deterioration in the appearance of the sheet caused by generation of a gel-form foreign substance in the sheet. In addition, since appropriate flexibility can be obtained, it is possible to prevent the occurrence of cracking in the solar cell element or the chipping of the thin film electrode during the lamination molding of the solar cell module.

When the content ratio of the α-olefin unit is equal to or less than 20 mol %, the crystallization rate of the ethylene/α-olefin copolymer becomes appropriate, and therefore a sheet extruded from an extruder does not become sticky, the sheet is easily peeled from a first cooling roll, and it is possible to efficiently obtain an encapsulating sheet for solar cell. In addition, since the sheet does not become sticky, blocking can be prevented, and the feeding property of the sheet is favorable. In addition, it is also possible to prevent the degradation of the heat resistance.

(Additives)

There is no particular limitation to additives in the embodiment, and the additives are appropriately selected from additives ordinarily used for the encapsulating sheet for solar cell and used. Examples of the additives ordinarily used for the encapsulating sheet for solar cell include an organic peroxide, a silane coupling agent, a crosslinking aid, an ultraviolet absorber, a heat-resistant stabilizer, a light stabilizer, and the like.

(Organic Peroxide)

The organic peroxide in the embodiment is used as a radical initiator during the graft modification of the silane coupling agent and the polyolefin-based resin, and furthermore, is used as a radial initiator during a crosslinking reaction when the polyolefin-based resin is lamination-molded to the solar cell module. When the silane coupling agent is graft-modified in the polyolefin-based resin, a solar cell module having a favorable adhesiveness to the glass plate, the backsheet, the cell, and the electrode is obtained. Furthermore, when the polyolefin-based resin is crosslinked, a solar cell module having excellent heat resistance and adhesiveness can be obtained.

There is no particular limitation to the organic peroxide in the embodiment as long as the organic peroxide is capable of graft-modifying the silane coupling agent in the polyolefin-based resin or crosslinking the polyolefin-based resin. A one-minute half-life temperature of the organic peroxide is preferably in a range of 100° C. to 170° C. in terms of the balance between the productivity during extrusion sheet molding and the crosslinking rate during the lamination molding of the solar cell module.

When the one-minute half-life temperature of the organic peroxide is equal to or higher than 100° C., it becomes difficult for a gel to be generated in the encapsulating sheet for solar cell obtained from the resin composition during the extrusion sheet molding, and therefore it is possible to suppress an increase in the torque of the extruder and to facilitate sheet molding. In addition, since it is possible to suppress the sheet surface becoming uneven due to a gel-form substance generated in the extruder, the degradation of the appearance can be prevented. In addition, since it is possible to prevent the occurrence of cracking in the sheet when a voltage is applied, a decrease in the dielectric breakdown voltage can be prevented. Furthermore, the degradation of the moisture permeability can also be prevented. In addition, since it is possible to suppress the sheet surface becoming uneven, the tight adhesiveness among the glass plate, the cell, the electrode, and the backsheet becomes favorable during the lamination process of the solar cell module, and the adhesiveness also improves. When the extrusion temperature of the extrusion sheet molding is decreased to equal to or lower than 90° C., while the molding is possible, the productivity significantly degrades. When the one-minute half-life temperature of the organic peroxide is equal to or lower than 170° C., it is possible to suppress a decrease in the crosslinking rate during the lamination molding of the solar cell module, and therefore it is possible to prevent the degradation of the productivity of the solar cell module.

In addition, it is also possible to prevent the degradation of the heat resistance and adhesiveness of the encapsulating sheet for solar cell.

A well-known organic peroxide can be used as the organic peroxide. Specific examples of the preferable organic peroxide having an one-minute half-life temperature in a range of 100° C. to 170° C. include dilauroyl peroxide, 1,1,3,3-tetramethylbutyl peroxy-2-ethylhexanoate, dibenzoyl peroxide, t-amylperoxy-2-ethylhexanoate, t-butylperoxy-2-ethylhexanoate, t-butylperoxy isobutyrate, t-butylperoxy maleate, 1,1-di(t-amylperoxy)-3,3,5-trimethylcyclohexane, 1,1-di(t-amylpeoxy)cyclohexane, t-amylperoxy isononanoate, t-amylperoxy normaloctoate, 1,1-di(t-butylperoxy)-3,3,5-trimethylcyclohexane, 1,1-di(t-butylperoxy)cyclohexane, t-butylperoxy isopropyl carbonate, t-butylperoxy-2-ethylhexylcarbonate, 2,5-dimethyl-2,5-di(benzoylperoxy)hexane, t-amyl-peroxybenzoate, t-butylperoxy acetate, t-butylperoxy isononanoate, 2,2-di(t-butylperoxy)butane, t-butylperoxy benzoate, and the like. Preferable examples thereof include dilauroyl peroxide, t-butylperoxy isopropyl carbonate, t-butyl proxy acetate, t-butylperoxy isononanoate, t-butylperoxy-2-ethylhexyl carbonate, t-butylperoxy benzoate, and the like. The above-described organic peroxide may be solely used, or a mixture of two or more organic peroxides may be used.

While varying depending on the kind of the organic peroxide, the addition amount of the organic peroxide is preferably in a range of 0.1 parts by weight to 3 parts by weight, and particularly preferably in a range of 0.2 parts by weight to 3 parts by weight with respect to 100 parts by weight of the polyolefin-based resin.

(Silane Coupling Agent)

The silane coupling agent in the embodiment is useful for improving the adhesiveness to a protective member, the solar cell element, and the like. For example, a compound having a hydrolysable group such as an alkoxy group along with an amino group or an epoxy group can be used as the silane coupling agent. Specific examples thereof that can be used include vinyltriethoxysilane, vinyl trimethoxysilane, vinyl tris(β-methoxyethoxysilane), γ-glycidoxypropyl trimethoxysilane, γ-aminopropyl triethoxysilane, and γ-methacryloxypropyl trimethoxysilane. Preferable examples thereof include γ-glycidoxypropyl methoxysilane, γ-aminopropyl triethoxysilane, γ-methacryloxypropyl trimethoxysilane, and vinyltriethoxysilane, all of which have favorable adhesiveness. The above-described silane coupling agents may be solely used or a mixture of two or more silane coupling agents may be used.

In addition, while varying depending on the kind of the silane coupling agent, the addition amount of the silane coupling agent is preferably in a range of 0.1 parts by weight to 4 parts by weight, and particularly preferably in a range of 0.1 parts by weight to 3 parts by weight with respect to 100 parts by weight of the polyolefin-based resin. When the addition amount of the silane coupling agent is equal to or more than the above-described lower limit value, the adhesiveness of the encapsulating sheet for solar cell is excellent. In addition, when the addition amount of the silane coupling agent is equal to or less than the above-described upper limit value, the balance between the cost and performance of the encapsulating sheet for solar cell is excellent.

(Crosslinking Aid)

The crosslinking aid in the embodiment accelerates the crosslinking reaction, and is effective for increasing the crosslinking degree of the polyolefin-based resin. For example, a well-known crosslinking aid of the related art ordinarily used for olefin-based resins can be used as the crosslinking aid. The crosslinking aid is a compound having two or more double bonds in the molecule. Specific examples thereof include monoacrylates such as t-butyl acrylate, lauryl acrylate, cetyl acrylate, stearyl acrylate, 2-methoxyethyl acrylate, ethylcarbitol acrylate, and methoxytripropylene glycol acrylate; monomethacrylates such as t-butyl methacrylate, lauryl methacrylate, cetyl methacrylate, stearyl methacrylate, methoxyethylene glycol methacrylate, and methoxypolyethylene glycol methacrylate; diacrylates such as 1,4-butanediol diacrylate, 1,6-hexanediol diacrylate, 1,9-nonanediol diacrylate, neopentyl glycol diacrylate, diethylene glycol diacrylate, tetraethylene glycol diacrylate, polyethylene glycol diacrylate, tripropylene glycol diacrylate, and polypropylene glycol diacrylate; dimethacrylates such as 1,3-butanediol dimethacrylate, 1,6-hexanediol dimethacrylate, 1,9-nonanediol dimethacrylate neopentyl glycol dimethacrylate, ethylene glycol dimethacrylate, diethylene glycol dimethacrylate, triethylene glycol dimethacrylate, and polyethylene glycol dimethacrylate; triacrylates such as trimethylol propane triacrylate, tetramethylol methane triacrylate, and pentaerythritol triacrylate; trimethacrylates such as trimethylol propane trimethacrylate and trimethylol ethane trimethacrylate; tetraacrylates such as pentaerythritol tetraacrylate and tetramethylol methane tetraacrylate; divinyl aromatic compounds such as divinyl benzene and di-i-propenyl benzene; cyanurates such as triallyl cyanurate and triallyl isocyanurate; diallyl compounds such as diallyl phthalate; and triallyl compounds; oximes such as p-quinone dioxime and p-p′-dibenzoyl quinone dioxime; and maleimides such as phenyl maleimide.

Among the above-described crosslinking aids, triacrylates such as diacrylate, dimethacrylate, divinyl aromatic compounds, trimethylol propane triacrylate, tetramethylol methane triacrylate, and pentaerythritol triacrylate; trimethacrylates such as trimethylol propane trimethacrylate and trimethylol ethane trimethacrylate; tetraacrylates such as pentaerythritol tetraacrylate and tetramethylol methane tetraacrylate; cyanurates such as triallyl cyanurate and triallyl isocyanurate; diallyl compounds such as diallyl phthalate; triallyl compounds; oximes such as p-quinone dioxime and p-p′-dibenzoyl quinonedioxime: and maleimides such as phenyl maleimide are more preferred. Furthermore, among the above-described crosslinking aids, triallyl isocyanurate is particularly preferred since the balance of the encapsulating sheet for solar cell after lamination between the restraint of air bubbles and crosslinking characteristics is excellent. The above-described crosslinking aids may be solely used or a mixture of two or more crosslinking aids may be used.

While varying depending on the kind of the crosslinking aid, the addition amount of the crosslinking aid is preferably in a range of 0.05 parts by weight to 5 parts by weight with respect to 100 parts by weight of the polyolefin-based resin. When the addition amount of the crosslinking aid is within the above-described range, it is possible to have an appropriate crosslinking structure and to improve heat resistance, mechanical properties, and adhesiveness.

(Ultraviolet Absorber)

Specific examples of the ultraviolet absorber in the embodiment include benzophenone-based ultraviolet absorbers such as 2-hydroxy-4-normal-octyloxylbenzophenone, 2-hydroxy-4-methoxybenzophenone, 2,2-dihydroxy-4-methoxybenzophenone, 2-hydroxy-4-methoxy-4-carboxybenzophenone, and 2-hydroxy-4-N-octoxybenzophenone; benzotriazole-based ultraviolet absorbers such as 2-(2-hydroxy-3,5-di-t-butylphenyl)benzotriazole and 2-(2-hydroxy-5-methylpheyl)benzotriazole; and salicyclic acid ester-based ultraviolet absorbers such as phenyl salicylate and p-octyl phenyl salicylate. The above-described ultraviolet absorbers may be solely used or a mixture of two or more crosslinking aids may be used.

While varying depending on the kind of the ultraviolet absorber, the addition amount of the ultraviolet absorber is preferably in a range of 0.005 parts by weight to 5 parts by weight with respect to 100 parts by weight of the polyolefin-based resin. When the addition amount of the ultraviolet absorber is within the above-described range, it is possible to sufficiently ensure an effect that improves the weather-resistant stability, and to prevent the degradation of the transparency or adhesiveness to the glass plate, the backsheet, the cell, the electrode, and aluminum of the encapsulating sheet for solar cell, which is preferable.

(Light Stabilizer)

As the light stabilizer in the embodiment, a hindered amine-based light stabilizer such as bis(2,2,6,6-tetramethyl-4-piperidyl)sebacate, poly[{6-(1,1,3,3-tetramehtylbutyl)amino-1,3,5-triazine-2,4-diyl}{(2,2,6,6-tetramethyl-4-piperidyl)imino}hexamethylene{(2,2,6,6-t etramethyl-4-piperidyl)imino}]; hindered pyperidine-based compounds; or the like is preferably used. The above-described light stabilizers may be solely used or a mixture of two or more light stabilizers may be used.

While varying depending on the kind of the light stabilizer, the addition amount of the light stabilizer is preferably in a range of 0.005 parts by weight to 5 parts by weight with respect to 100 parts by weight of the polyolefin-based resin. When the addition amount of the ultraviolet absorber is within the above-described range, it is possible to sufficiently ensure an effect that improves the weather-resistant stability, and to prevent the degradation of the transparency or adhesiveness to the glass plate, the backsheet, the cell, the electrode, and aluminum of the encapsulating sheet for solar cell, which is preferable.

(Heat-Resistant Stabilizer)

Specific examples of the heat-resistant stabilizer in the embodiment include phosphite-based heat-resistant stabilizer such as tris(2,4-di-tert-butylphenyl)phosphite, bis[2,4-bis(1,1-dimethylethyl)-6-methylphenyl]ethylester phosphorous acid, tetrakis(2,4-di-tert-butylphenyl) [1,1-biphenyl]-4,4′-diylbisphosphonite and bis(2,4-di-tert-butylphenyl)pentaerythritol diphosphite; lactone-based heat-resistant stabilizers such as a reaction product of 3-hydroxy-5,7-di-tert-butyl-furan-2-on and o-xylene; hindered phenol-based heat-resistant stabilizers such as 3,3′,3″,5,5′,5″-hexa-tert-butyl-a,a′,a″-(methylene-2,4,6-triyl)tri-p-cresol, 1,3,5-trimethyl-2,4,6-tris(3,5-di-tert-butyl-4-hydroxyphenyl)benzylbenzene, pentaerythritol tetrakis[3-(3,5-di-tert-butyl-4-hydroxyphenyl)propionate], octadecyl-3-(3,5-di-tert-butyl-4-hydroxyphenyl)propionate, and thiodiethylene bis[3-(3,5-di-tert-butyl-4-hydroxyphenyl)propionate]; sulfur-based heat-resistant stabilizers; amine-based heat-resistant stabilizers; and the like. Among the above-described heat-resistant stabilizers, the phosphite-based heat-resistant stabilizers and the hindered phenyl-based heat-resistant stabilizers are preferred. The above-described heat-resistant stabilizers may be solely used or a mixture of two or more heat-resistant stabilizers may be used.

While varying depending on the kind of the heat-resistant stabilizers, the addition amount of the heat-resistant stabilizers is preferably in a range of 0.005 parts by weight to 5 parts by weight with respect to 100 parts by weight of the polyolefin-based resin. When the addition amount of the ultraviolet absorber is within the above-described range, it is possible to sufficiently ensure an effect that improves the resistance against a high temperature and a high humidity, the resistance against the heat cycle and the heat-resistant stability, and to prevent the degradation of the transparency or adhesiveness to the glass plate, the backsheet, the cell, the electrode, and aluminum of the encapsulating sheet for solar cell.

(Other Additives)

As the additives of the embodiment, a variety of additives other than the above-described additives can be appropriately contained within the scope of the purpose of the invention. For example, it is possible to appropriately add one or more additives selected from a variety of resins other than the polyolefin-based resin, a variety of rubber, a plasticizer, a filler, a pigment, a dye, an antioxidant, an antistatic agent, an antimicrobial agent, an antifungal agent, a flame retardant, a crosslinking aid, a light diffusion agent, a discoloration inhibitor, and a dispersant.

(Pellet Containing the Polyolefin-Based Resin as a Main Component)

There is no particular limitation to a method for manufacturing a pellet containing the polyolefin-based resin as a main component in the embodiment, and examples thereof include a method in which the polyolefin-based resin is melted and kneaded using a uniaxial or biaxial extrusion molder so as to be extruded in a strand shape or a sheet shape, and the polyolefin-based resin is cut into a pellet shape so as to obtain a predetermined grain size using a pelletizer. Meanwhile, the pellet may appropriately contain the above-described additives in advance within the purpose of the invention.

In addition, the average grain diameter in the pellet is preferably in a range of 0.2 mm to 10 mm. When the average grain diameter in the pellet is within the above-described range, the balance between the below-described stirring property of the pellet containing the polyolefin-based resin as a main component and the soaking time of the additives in the pellet is excellent.

(Manufacturing Method)

Subsequently, the manufacturing method will be described.

The method for manufacturing the encapsulating sheet for solar cell of the embodiment includes a step in which an additive A is soaked inside a pellet containing a polyolefin-based resin as a main component, thereby producing an additive-containing pellet, and a step in which the additive-containing pellet is supplied to an extrusion molder, and is molded by extrusion into a sheet shape while being melted and kneaded in a cylinder.

(The Step of Adjusting the Additive A)

The property of the additive A soaked in advance inside the pellet is preferably a liquid phase since the soaking property inside the pellet is excellent.

In addition, it is preferable to adjust in advance the additive A by dissolving or dispersing at least one solid-phase solid additive in a liquid-phase liquid additive. When the solid additive is dissolved or dispersed in the liquid additive, it is possible to improve the soaking property of the solid additive inside the pellet. At this time, a dilute solvent may be appropriately added to improve the dissolution property or dispersion property of the solid additive.

There is no particular limitation to the method for dissolving or dispersing the solid additive, and it is possible to adjust a solution containing the additive by, for example, feeding the liquid additive into a stirring and mixing device such as a Henschel mixer, a tumbler mixer, a super mixer, or a rotary mixer, adding the solid additive to the liquid additive, and stirring and mixing the mixture.

There is no particular limitation to the temperature at which the mixture is stirred and mixed, and the temperature may be at room temperature or at a temperature in a range of approximately 30° C. to 120° C. to increase the stirring efficiency. When the temperature is equal to or higher than the above-described lower limit value, the dissolution or dispersion rate of the solid additive can be improved, and therefore it is possible to improve the productivity of the encapsulating sheet for solar cell. In addition, when the temperature is equal to or lower than the upper limit value, it is possible to suppress the degradation of the additive.

There is no particular limitation regarding how long the mixture is kneaded and mixed, but it is preferable to knead and mix the mixture until the solid additive appears to be uniformly dissolved and dispersed.

Here, the liquid additive in the embodiment refers to a liquid-phase additive at room temperature. There is no particular limitation to the liquid additive in the embodiment, and mainly, the organic peroxide, the silane coupling agent, and the crosslinking aid among the above-described additives correspond to the liquid additives.

In addition, the solid additive in the embodiment refers to a solid-phase additive at room temperature. There is no particular limitation to the solid additive in the embodiment, and mainly, the ultraviolet absorber, the heat-resistant stabilizer, and the light stabilizer among the above-described additives correspond to the solid additives.

(The Step for Producing the Additive-Containing Pellet)

Next, the step for manufacturing the additive-containing pellet by soaking the additive A inside the pellet containing the polyolefin-based resin as a main component will be described.

First, the pellet containing the polyolefin-based resin as a main component and the adjusted additive A are supplied to a stirring and mixing device, for example, a Henschel mixer, a tumbler mixer, a super mixer, or a rotary mixer.

Next, the pellet containing the polyolefin-based resin as a main component and the adjusted additive A are brought into contact with each other by operating the stirring and mixing device, thereby soaking the additive A inside the pellet and producing the additive-containing pellet. Meanwhile, the pellet is preferably supplied in the full amount before the stirring and mixing device is rotated. On the other hand, the additive A may be supplied in the full amount or may be divided and supplied before the stirring and mixing device is rotated. The additive A is preferably divided and supplied to the stirring and mixing device since it is possible to more uniformly soak the additive A inside the pellet.

The dynamic motor value of the stirring and mixing device during the stirring and mixing and the integrated dynamic motor value of the stirring and mixing device during the stirring and mixing are design matters that can be determined depending on the soaking rate or treatment amount of the additive.

There is no particular limitation to the temperature of the pellet when the additive A is soaked inside the pellet containing the polyolefin-based resin as a main component, and the temperature may be at room temperature or heated to a temperature in a range of approximately 30° C. to 50° C. to increase the soaking rate. When the temperature is equal to or higher than the above-described lower limit value, it is possible to improve the soaking rate of the solution containing the additive inside the pellet, and therefore it is possible to improve the productivity of the encapsulating sheet for solar cell. In addition, when the temperature is equal to or lower than the upper limit value, it is possible to further suppress the degradation of the additive. In addition, it is possible to further suppress the fusion between the pellets or the fusion of the pellet to the stirring and mixing device. Meanwhile, the temperature of the pellet refers to the surface temperature of the pellet.

There is no particular limitation regarding how long the additive A is soaked inside the pellet containing the polyolefin-based resin as a main component since the time varies depending on the treatment amount, but the time is preferably in a range of 0.2 hours to 3 hours, and more preferably in a range of 0.3 hours to 2 hours. When the time is equal to or more than the above-described lower limit value, it is possible to sufficiently soak the additive A into the inside of the pellet. When the time is equal to or less than the above-described upper limit value, it is possible to further suppress the inactivation of the additive. Meanwhile, whether or not the soaking of the additive A inside the pellet is completed can be checked using the dynamic motor value of the stirring and mixing device. When the soaking is completed, moisture in the pellet is removed, and therefore the dynamic value of the motor abruptly increases. When the dynamic motor value is used for checking, it is possible to check whether or not the soaking of the additive is completed into a resin having a slow soaking rate of the additive A such as the polyolefin-based resin.

According to the method for manufacturing an encapsulating sheet for solar cell in the embodiment, when the additive A is soaked in advance inside the pellet containing the polyolefin-based resin as a main component, it is possible to uniformly distribute the additive A in the pellet while suppressing the deterioration of the additive A. Therefore, it is possible to stably obtain an encapsulating sheet for solar cell in which the additive A is uniformly dispersed.

(The Step of Molding the Additive-Containing Pellet into a Sheet Shape by Extrusion)

Subsequently, a step in which the above-described additive-containing pellet is supplied to an extrusion molder, and is molded by extrusion into a sheet shape while being melted and kneaded in a cylinder will be described.

A variety of well-known biaxial or uniaxial extrusion molders can be used as the extrusion molder in the embodiment. The extrusion molder includes a hopper in the most upstream section as a raw material supply opening and a die such as a T die or a ring die at the tip portion in the most downstream section. A screw is disposed in the cylinder, the pellet injected into the cylinder is heated and melted using a heater disposed on the outside of the cylinder, is sent in the downstream direction using a rotating screw, and is extruded into a sheet shape from the T die or the like. A biaxial extrusion molder is preferred as the extrusion molder due to its excellent kneading performance.

The additive-containing pellet is supplied to the inside of the extrusion molder from the hopper, melted and kneaded, and extruded into a sheet shape from the die, such as a T die, installed at the tip portion of the extruder, thereby obtaining an encapsulating sheet for solar cell.

There is no particular limitation to the extrusion temperature, but it is preferable to melt and knead the additive-containing pellet at a temperature lower than the one-hour half-life temperature of the organic peroxide being used and extrude the additive-containing pellet into a sheet shape. Then, it is possible to suppress the inactivation of the organic peroxide.

Specifically, the extrusion temperature is in a range of 100° C. to 130° C. When the extrusion temperature is set to equal to or higher than the above-described lower limit value, it is possible to improve the productivity of an encapsulating sheet for solar cell. In addition, when the extrusion temperature is set to equal to or lower than the above-described upper limit value, it is possible to suppress the deterioration of the additive. In addition, it is possible to suppress the gelatinization of the resin.

In addition, the encapsulating sheet for solar cell extruded from the T die or the like is cooled and solidified using cooling rolls while maintaining a uniform thickness, and is wound using a winding machine. V0 (the rate [mm·sec⁻¹] of the thermoplastic resin being extruded from the extrusion molder), V1 (the drawing rate [mm·sec⁻¹] of the sheet-shaped thermoplastic resin), and Z (the air gap [mm] between the die and the cooling rolls) are set so as to satisfy d∈/dt<ω_{d}. Meanwhile, it is possible to set the above-described parameters so that V1 and V0 become a larger value and Z becomes a smaller value in a range in which d∈/dt<ω_{d} is satisfied.

(The Step of Further Adding an Additive B into the Cylinder)

In the step of molding the additive-containing pellet by extrusion into a sheet shape in the embodiment, an additive B that is identical to or different from the additive A may be further added to a section between the raw material supply opening and the screw tip in the cylinder using a liquid injection nozzle. A well-known nozzle can be used as the liquid injection nozzle.

Then, the amount of the additive A that is soaked inside the pellet in advance can be decreased, the soaking time of the additive can be shortened, and it is possible to improve the productivity of the encapsulating sheet for solar cell. Particularly, since the polyolefin-based resin has a slower soaking rate of the additive compared with a polar copolymer such as an ethylene/vinyl acetate copolymer, a method is effective in which the additive is dividedly added as additive A and additive B, the additive A being soaked inside the pellet in advance and the additive B being added from the liquid injection nozzle. Then, it is possible to further improve the productivity of the encapsulating sheet for solar cell containing the polyolefin-based resin as a main component. Meanwhile, the property of the additive B is also, similar to the property of the additive A, preferably a liquid phase since the soaking property inside the pellet is excellent.

There is no particular limitation to the amount of the additive B being added from the liquid injection nozzle; however, when the total amount of the additive A and the additive B is set to 100 parts by weight, the amount of the additive B is preferably equal to or more than 0.01 parts by weight and equal to or less than 10 parts by weight, and more preferably equal to or more than 0.1 parts by weight and equal to or less than 5 parts by weight. When the amount of the additive B is within the above-described range, the balance between the uniformity of the additive in the sheet and the productivity of the sheet is superior.

In addition, it is preferable that the additive B being injected into the cylinder does not substantially contain at least one of the organic peroxide and the silane coupling agent. Since the organic peroxide and the silane coupling agent are dangerous substances, in a case in which the organic peroxide and the silane coupling agent are directly injected into the cylinder, a special facility is required as a safety measure of the extrusion molder. Therefore, when the additive B being injected into the cylinder does not substantially contain the organic peroxide or the silane coupling agent, it is possible to simplify the production facility.

Meanwhile, in the embodiment, the additive A preferably contains at least one of the organic peroxide and the silane coupling agent as the liquid additives.

In addition, in the embodiment, the additive B preferably contains the crosslinking aid. Among the above-described liquid additives, the crosslinking aid has a slower soaking rate into the polyolefin-based resin than other liquid additives. Therefore, when the crosslinking aid is contained in the additive B being injected into the cylinder, it is possible to decrease the amount of the crosslinking aid in the additive A that is soaked inside the pellet in advance. As a result, the soaking time of the additive A inside the pellet can be shortened, and it is possible to further improve the productivity of the encapsulating sheet for solar cell containing the polyolefin-based resin as a main component.

When the total of the crosslinking aid used for the manufacturing of the encapsulating sheet for solar cell of the embodiment is set to 100% by weight, the crosslinking aid contained in the additive B is preferably equal to or more than 0.05% by weight and equal to or less than 5% by weight, and more preferably equal to or more than 0.5% by weight and equal to or less than 3% by weight. When the total of the crosslinking aid is within the above-described range, the soaking time of the additive A inside the pellet can be further shortened, and it is possible to further improve the productivity of the encapsulating sheet for solar cell containing the polyolefin-based resin as a main component.

Meanwhile, the method for manufacturing an encapsulating sheet for solar cell of the embodiment is particularly effective when a pellet containing as a main component a polyolefin-based resin having a weight change rate of equal to or less than 3% by weight when being soaked in the liquid crosslinking aid at 150° C. for three hours is used as a raw material. Since the above-described polyolefin-based resin has a particularly slow soaking rate of the additive, the polyolefin-based resin and the additive are more insufficiently kneaded in the extrusion molder, and the additive is likely to segregate in the sheet. Therefore, in a case in which the above-described polyolefin-based resin is used, the method for manufacturing an encapsulating sheet for solar cell of the embodiment is particularly effective.

Meanwhile, the liquid-phase crosslinking aid used when the weight change rate of the polyolefin-based resin with respect to the crosslinking aid is measured is, for example, triallyl isocyanurate.

As described above, in the method for manufacturing the encapsulating sheet for solar cell in the embodiment, the additives are made to pass through the extrusion molder only once. Therefore, it is possible to suppress the inactivation of a variety of additives due to heating or the frictional heat with screw blades in the extrusion molder, and to stably manufacture the encapsulating sheet for solar cell having excellent qualities.

In addition, in the method for manufacturing the encapsulating sheet for solar cell in the embodiment, it is preferable to carry out an embossing process on the surface of the sheet after the sheet is extruded in a sheet shape to improve the deaeration property.

There is no particular limitation to the method for carrying out the embossing process on the surface of the sheet, and a method in which the sheet extruded from a T die is supplied between an embossing roll provided with an embossing shape on the surface and a rubber roll disposed opposite to the embossing roll, and an embossing process is carried out on the surface of the sheet while the embossing roll is pressed on the molten sheet can be used. Meanwhile, it is also possible to melt the obtained sheet again by heating and carry out an embossing process.

In the embodiment, the obtained encapsulating sheet for solar cell can be used as an encapsulating sheet for solar cell in a sheet form that has been cut in accordance with the size of the solar cell module or in a roll form that can be cut in accordance with the size immediately before the solar cell module is produced.

The thickness of the encapsulating sheet for solar cell in the embodiment is not particularly limited, and is generally in a range of 0.01 mm to 2 mm, preferably in a range of 0.1 mm to 1.2 mm, and more preferably in a range of 0.3 mm to 0.9 mm. When the thickness is within the above-described range, it is possible to suppress the breakage of the glass plate, the solar cell element, the thin film electrode, and the like during the lamination step and to sufficiently ensure light transmittance, thereby obtaining a great light power generation amount. Furthermore, the lamination molding of the solar cell module at a low temperature is possible, which is preferable.

Next, the method for manufacturing a solar cell of the embodiment will be described. The method for manufacturing the solar cell of the embodiment includes an encapsulating step in which a laminate is formed by sandwiching the solar cell using the encapsulating sheets for solar cell of the embodiment, and a pressure is added to the laminate with a press pressure that is equal to or more than 0.4 atmospheric pressures and equal to or less than 1 atmospheric pressure while the laminate is heated at a temperature that is equal to or higher than 140° C. and equal to or lower than 200° C. for 5 minutes to 30 minutes, thereby integrating the laminate.

The laminate may be a laminate in which, for example, a transparent surface protective member (for example, a glass plate), a first encapsulating sheet for solar cell, the solar cell, a second encapsulating sheet for solar cell, and a back-surface protective member (for example, a backsheet in which a variety of sheets are laminated) are laminated in this order. The configurations of the transparent surface protective member, the solar cell, and the back-surface protective member can be realized according to the related art, and thus will not be described herein.

The details of other steps and the encapsulating step can be realized according to the related art.

### EXAMPLES

### Example 1

### Synthesis of an Ethylene/α-Olefin Copolymer

### Synthesis Example 1

A toluene solution of methyl aluminoxane was supplied as a co-catalyst at a rate of 8.0 mmol/hr, and a hexane slurry of bis (1,3-dimethylcyclopentadienyl) zirconium dichloride and a hexane solution of triisobutylaluminum were supplied at rates of 0.025 mmol/hr and at 0.5 mmol/hr respectively as main catalysts to one supply opening of a continuous polymerization vessel having stirring blades and an inner volume of 50 L, and normal hexanone which was used as a catalyst solution and a polymerization solvent and was dehydrated and purified so that the total of the dehydrated and purified normal hexanone became 20 L/hr was continuously supplied. At the same time, ethylene, 1-butene, and hydrogen were continuously supplied at rates of 3 kg/hr, 15 kg/hr, and 5 NL/hr respectively to another supply opening of the polymerization vessel, and continuous solution polymerization was carried out under conditions of a polymerization temperature of 90° C., a total pressure of 3 MPaG, and a retention time of 1.0 hour. The normal hexane/toluene solution mixture of the ethylene/α-olefin copolymer generated in the polymerization vessel was continuously discharged through a discharge opening provided in the bottom portion of the polymerization vessel, and was guided to a coupling pipe in which a jacket portion was heated using 3 kg/cm² to 25 kg/cm² steam so that the normal hexane/toluene solution mixture of the ethylene/α-olefin copolymer reached a temperature in a range of 150° C. to 190° C.

Meanwhile, a supply opening through which methanol that is a catalyst-inactivating agent is injected was provided immediately before the coupling pipe, and methanol was injected at a rate of approximately 0.75 L/hr so as to combine with the normal hexane/toluene solution mixture of the ethylene/α-olefin copolymer. The normal hexane/toluene solution mixture of the ethylene/α-olefin copolymer maintained at approximately 190° C. in the steam jacket-equipped coupling pipe was continuously fed to a flash chamber by adjusting the degree of the opening of a pressure control valve provided at the terminal portion of the coupling pipe so as to maintain approximately 4.3 MPaG. Meanwhile, when the normal hexane/toluene solution mixture was transported to the flash chamber, the solution temperature and the degree of the opening of the pressure-adjusting valve were set so that the pressure in the flash chamber was maintained at approximately 0.1 MPaG and the temperature of a vapor portion in the flash chamber was maintained at approximately 180° C. After that, the mixture was fed through a single screw extruder in which the die temperature was set to 180° C., the resultant strand was cooled in a water vessel, and the strand was cut using a pellet cutter, thereby obtaining an ethylene/α-olefin copolymer in a pellet form. The yield was 2.2 kg/hr. The properties of the obtained ethylene/α-olefin copolymer 1 are described below.

Ethylene/1-butene=86/14 (mol/mol), density=0.87 g/cm³, MFR (ASTM D1238, a temperature of 190° C., and a load of 2.16 kg)=20 g/10 minutes, and shore A hardness=70

(Step of Producing Sheets)

50 parts by weight of an organic peroxide (2-ethylhexanoxycarbonyl-t-butyl peroxide) and 50 parts by weight of a silane coupling agent (vinyltriethoxysilane) were blended and stirred at room temperature for 30 minutes in a first stirring vessel having stirring blades and an inner volume of 50 L, thereby preparing a sufficiently stirred and mixed additive A.

Next, a pellet of the above-described ethylene/α-olefin copolymer was held in a 200 L inverted conical stirring vessel having spiral ribbon blades, and stirred for 30 minutes under heating at 40° C. in a status in which 1 part by weight of the additive A was added to 100 parts by weight of the pellet. As a result, a soaked pellet in a state in which the additive A was soaked and dried in the pellet of the ethylene/α-olefin copolymer was obtained.

Next, 1 part by weight of an antioxidant (IRGANOX 1010) and 99 parts by weight of a crosslinking aid (triallyl isocyanurate) were blended, stirred at 35° C. for two hours, and sufficiently melted in a second stirring vessel having stirring blades and an inner volume of 50 L, thereby obtaining an additive B.

Next, the soaked pellet was supplied to a raw material supply opening of a biaxial extrusion molder using a weight-type feeder. Furthermore, the additive B was supplied to a liquid addition nozzle mounted in the central portion between the raw material supply opening and the screw tip using a plunger pump, and the additive was injected into a cylinder from the liquid addition nozzle. At this time, the liquid addition amount was adjusted to become 1 part with respect to 100 parts of the resin. The extruder had a T die installed therein, and extruded molten sheets were cooled and solidified using cooling rolls, and then wound. Meanwhile, the distance from the T die to the cooling rolls was 300 mm.

At this time, the supply rate of the soaked pellet was set to 20 kg/H, and 0.5 mm-thick resin sheets were obtained. The resin temperature at the T die outlet was 103° C. Meanwhile, ω_{d} [sec⁻¹], V0 [mm·sec⁻¹], V1 [mm·sec⁻¹], and Z [mm] were adjusted so as to satisfy the above-described relationship of d∈/dt<ω_{d}.

### Example 2

### Synthesis Example 2

The supply amounts of 1-butene, hydrogen, and normal hexane in Synthesis Example 1 were adjusted, and an ethylene/α-olefin copolymer 2 was obtained. The properties of the obtained ethylene/α-olefin copolymer 2 were as described below.

Ethylene/1-butene=86/14 (mol/mol), density=0.87 g/cm³, MFR (ASTM D1238, a temperature of 190° C., and a load of 2.16 kg)=5.4 g/10 minutes, and shore A hardness=70

(Step of Producing Sheets)

Soaking was carried out in the same manner as in Example 1, and the soaked pellet was supplied to the biaxial extruder. The resin temperature at the T die outlet was 108° C. Meanwhile, ω_{d} [sec⁻¹], V0 [mm·sec⁻¹], V1 [mm·sec⁻¹], and Z [mm] were adjusted so as to satisfy the above-described relationship of d∈/dt<ω_{d}.

### Comparative Example 1

### Step of Producing Sheets

25 parts by weight of an organic peroxide (2-ethylhexanoxycarbonyl-t-butyl peroxide), 25 parts by weight of a silane coupling agent (vinyltriethoxysilane), 49 parts by weight of a crosslinking aid (triallyl isocyanurate), and 1 part by weight of an antioxidant (IRGANOX 1010) were blended and stirred at 35° C. for two hours in a stirring vessel having stirring blades and an inner volume of 50 L, thereby preparing a sufficiently melted and mixed additive C.

Next, an EVA pellet (VA33%) was held in a 50 L inverted conical stirring vessel having a spiral ribbon blade, and stirred for 30 minutes under heating at 40° C. in a status in which 2 parts by weight of the additive C was added to 100 parts by weight of the pellet. As a result, a soaked EVA pellet in a state in which the additive C was soaked and dried in the pellet of EVA was obtained.

Next, the soaked pellet was supplied to the raw material supply opening of the biaxial extrusion molder using the weight-type feeder. The extruder had a T die installed therein, and extruded molten sheets were cooled and solidified using cooling rolls, and then were wound.

At this time, the supply rate of the soaked pellet was set to 20 kg/H, and 0.5 mm-thick resin sheets were obtained. The resin temperature at the T die outlet was 110° C. Meanwhile, ω_{d} [sec⁻¹], V0 [mm·sec⁻¹], V1 [mm·sec⁻¹], and Z [mm] were adjusted so as not to satisfy the above-described relationship of d∈/dt<ω_{d}.

### Comparative Example 2

### Step of Producing Sheets

Soaking was carried out in the same manner as in Example 2, and the soaked pellet was supplied to the biaxial extruder. Meanwhile, the distance from the T die to the cooling rolls was 100 mm. The resin temperature at the T die outlet was 108° C. Meanwhile, ω_{d} [sec⁻¹] V0 [mm·sec⁻¹], V1 [mm·sec⁻¹], and Z [mm] were adjusted so as not to satisfy the above-described relationship of d∈/dt<ω_{d}.

<Test>

The respective sheets of Examples 1 and 2 and Comparative Examples 1 and 2 were cut into a square shape having a planar shape of 100 mm×100 mm (L=100 mm), thereby obtaining square sheets. After that, a heat treatment was carried out on the square sheets using a hot plate at the atmospheric pressure and 150° C. for 15 minutes. After that, the square sheets were mounted on a flat surface on which powder was dispersed, and were left to stand until the sheets were naturally cooled to room temperature.

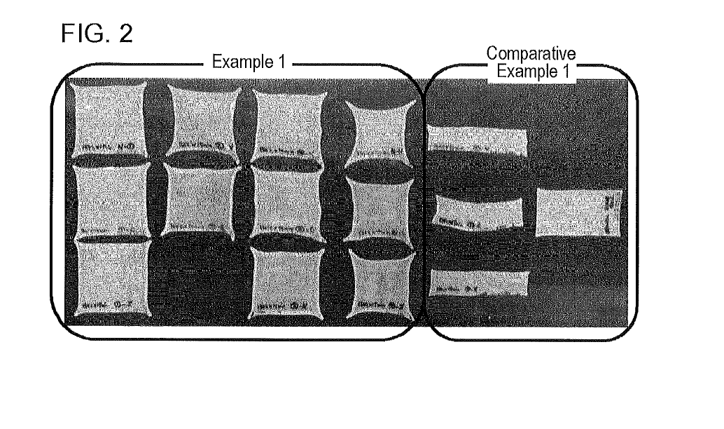

The states of Example 1 and Comparative Example 1 after being left to stand are illustrated in FIG. 2. It is found from the drawing that the sheets shrank substantially in an isotropic manner in Example 1, and the sheets shrank in an anisotropic manner in Comparative Example 1. All illustrated sheets of Example 1 satisfied 0≦|(M1−M2)/L|≦0.4, but all illustrated sheets of Comparative Example 1 failed to satisfy 0≦|(M1−M2)/L|≦0.4. Example 2 satisfied 0≦|(M1−M2)/L|≦0.4, but Comparative Example 2 failed to satisfy 0≦|(M1−M2)/L|≦0.4.

In addition, all illustrated sheets of Example 1 satisfied 0.3≦M1/L≦1 and 0.3≦M2/L≦1, but all illustrated sheets of Comparative Example 1 failed to satisfy 0.3≦M1/L≦1 and 0.3≦M2/L≦1.

The MFR, extrusion rates, air gaps (the distances from the T die to the cooling rolls), the measured values and shrinkage rate of the shortest length M1 in the first direction (machine direction (MD)), the measured values and shrinkage rate of the shortest length M2 in the second direction (transverse direction (TD)), (CL-1) value of |(M1−M2)/L|, and (CL-3) values of M1/L and M2/L in Examples 1 and 2 and Comparative Example 2 are summarized in Table 1. Meanwhile, MD represents the machine direction, that is, a direction in which the sheet is wound. TD represents a direction perpendicular to MD.

TABLE 1

| | | | | MD (M1) | | | | | | |
|---|---|---|---|---|---|---|---|---|---|---|
| | MFR | Extrusion | Air | Measured | | TD (M2) | | | | |
| | g/10 | rate | gap | value | Shrinkage | Measured | Shrinkage | | CL-3 | |
| | min | (kg/h) | (mm) | (mm) | rate (%) | value (mm) | rate (%) | CL-1 | M1/L | M2/L |
| Example 1 | 20 | 20 | 300 | 80 | 20 | 84 | 16 | 0.04 | 0.80 | 0.84 |
| Example 2 | 5.4 | 20 | 300 | 83 | 17 | 87 | 13 | 0.04 | 0.83 | 0.87 |
| Comparative | 5.4 | 20 | 100 | 66 | 34 | 95 | 5 | 0.29 | 0 66 | 0.95 |
| Example 2 | | | | | | | | | | |

Thus far, the embodiments of the invention have been described, but the embodiments are simply examples of the invention, and the invention is still capable of employing a variety of configurations other than the above-described configuration.

The present application claims priority based on Japanese Patent Application No. 2012-30880 filed on Feb. 15, 2012, and the contents of which are incorporated herein by reference.

1. An encapsulating sheet for solar cell for encapsulating a solar cell,
wherein, in a case in which a square sheet obtained by cutting the sheet so that a planar shape becomes a square shape is heated at an atmospheric pressure and 150° C. for 15 minutes and is thus thermally shrunk,
when a length of one side of the square sheet before being thermally shrunk is represented by L, a direction in parallel with a first side is considered as a first direction, and a direction perpendicular to the first side is considered as a second direction, and
in the thermally-shrunk square sheet, a shortest length in the first direction is represented by M1, and a shortest length in the second direction is represented by M2,
0≦|(M1−M2)/L|≦0.4 is satisfied.

2. The encapsulating sheet for solar cell according to claim 1 obtained by forming a polyolefin resin film.

3. The encapsulating sheet for solar cell according to claim 2,
wherein 0.3≦M1/L≦1 and 0.3≦M2/L≦1 are satisfied.

4. The encapsulating sheet for solar cell according to claim 1,
wherein the square sheet satisfies 100 mm≦L≦150 mm.

5. A solar cell,
wherein a solar cell is encapsulated using the encapsulating sheets for solar cell according to claim 1.

6. A method for manufacturing a solar cell, comprising:
an encapsulating step in which a laminate obtained by sandwiching a solar cell using the encapsulating sheets for solar cell according to claim 1 is formed, and the laminate is integrated by heating and pressurization.

7. The method for manufacturing a solar cell according to claim 6,
wherein, in the encapsulating step, a pressure is added to the laminate with a press pressure that is equal to or more than 0.4 atmospheric pressures and equal to or less than 1 atmospheric pressure while heating the laminate at a temperature that is equal to or higher than 140° C. and equal to or lower than 200° C. for equal to or more than 5 minutes and equal to or less than 30 minutes.
